(19) United States
(12) Patent Application Publication
(10) Pub. No.: US 2024/0353768 A1
(43) Pub. Date: Oct. 24, 2024

(54) MEASURING DEVICE AND METHOD FOR INSPECTING PHOTOMASKS INTENDED FOR EUV MICROLITHOGRAPHY

(71) Applicant: Carl Zeiss SMT GmbH, Oberkochen (DE)

(72) Inventors: Lutz Brekerbohm, Hardegsen (DE); Senthil Lakshmanan, Erfurt (DE)

(21) Appl. No.: 18/638,890

(22) Filed: Apr. 18, 2024

(30) Foreign Application Priority Data
Apr. 21, 2023 (DE) 102023110173.0

(51) Int. Cl. G03F 7/00; G03F 1/84

(52) U.S. Cl. CPC G03F 7/70983; G03F 1/84; G03F 7/70033; G03F 7/702; G03F 7/70833; G03F 7/70858

(57) ABSTRACT

A measuring device for inspecting photomasks comprises an illumination system, a projection lens and an EUV image sensor. EUV radiation emitted by an EUV radiation source is guided via the illumination system to a photomask. EUV radiation reflected at the photomask is guided via the projection lens to the EUV image sensor such that the photomask is imaged on the EUV image sensor. The measuring device comprises a frame component part, the frame component part carrying a pellicle. The pellicle is arranged between the photomask and the projection lens such that the EUV radiation reflected at the photomask passes through the pellicle. The invention also relates to a method for inspecting photomasks.

### CROSS-REFERENCE TO RELATED APPLICATION

This application claims priority under 35 U.S.C. § 119 from German Application No. 10 2023 110 173.0, filed on Apr. 21, 2023, the entire contents of which are incorporated herein by reference.

### TECHNICAL FIELD

The invention relates to a measuring device and a method for inspecting photomasks intended for EUV microlithography.

### BACKGROUND

Photomasks are used in microlithographic projection exposure apparatuses, which are used to produce integrated circuits with particularly small structures. The photomask illuminated by very short-wave extreme ultraviolet radiation (EUV radiation) is imaged onto a lithography object in order to transfer the mask structure to the lithography object.

To ensure a high quality of the image created on the lithography object, it is necessary for the photomask to be true to size and not adversely affected by contamination. It is known practice to subject photomasks to an inspection, either prior to the operation in a microlithographic projection exposure apparatus or during an interruption of operation. To this end, a so-called aerial image of the photomask or of a portion of the photomask is created, the photomask in the process being imaged not on a lithography object but on an EUV image sensor. Using the imaging onto the EUV image sensor as a basis, it is possible to make an assessment as to whether the photomask is without defects and contaminations.

The mask inspection should be performed in such a way that the measurement result is not falsified by contamination. In particular, the photomask should be prevented from experiencing contamination as a result of the mask inspection procedure.

### SUMMARY

The invention is based on the aspect of presenting a measuring device and a method for mask inspection, in the case of which the risk of contamination is reduced. The aspect is achieved by the features of the independent claims. Advantageous embodiments are specified in the dependent claims.

The measuring device according to the invention for inspecting photomasks comprises an illumination system, a projection lens and an EUV image sensor. EUV radiation emitted by an EUV radiation source is guided via the illumination system to a photomask. EUV radiation reflected at the photomask is guided via the projection lens to the EUV image sensor such that the photomask is imaged on the EUV image sensor. The measuring device comprises a frame component part which carries a pellicle. The pellicle is arranged between the photomask and the projection lens such that the EUV radiation reflected at the photomask passes through the pellicle.

It was found that the use of measuring devices for inspecting EUV photomasks harbours a significant risk of the examined photomask experiencing contamination as a result of the inspection procedure. Even though the inspection procedure is normally carried out in a vacuum atmosphere, it is not possible to avoid particles entirely. For example, particles are generated continually by friction when components of the measuring device are mechanically moved relative to one another. The invention has recognized that the damaging effects of these unavoidable particles can be significantly reduced by virtue of avoiding the situation where the particles are allowed to deposit on the photomask. The invention proposes to provide the measuring device with a pellicle which is arranged between the photomask and the projection lens such that the EUV radiation reflected at the photomask passes through the pellicle.

Although this does not prevent the presence of particles in the measuring device, it does reduce the negative effects of the particles because the particles are unable to be deposited on the photomask. This would be particularly damaging because entire batches of semiconductor component parts which were exposed with a contaminated photomask might become unusable.

The prior art has disclosed pellicles stretched directly over the photomask and likewise having the purpose of protecting the photomask from particles. The pellicle according to the invention, which is a constituent part of the measuring device, should be distinguished from these known pellicles. For example, it is possible to remove the examined photomask from the measuring device while the pellicle according to the invention remains by the measuring device.

A pellicle refers to a membrane that is designed to allow EUV radiation to pass but suppresses a passage of particles. Since matter is generally highly absorptive with regards to EUV radiation, material and structure of the pellicle must be carefully adapted in view of a use in a measuring device for mask inspection. For instance, unlike in the case of visible light, it is not possible to use glass panes as a protection against contamination. The EUV radiation would be absorbed in the glass pane and would not arrive at the image sensor with a sufficient intensity.

In an embodiment, the pellicle is a CNT (carbon nanotubes) pellicle, i.e. a membrane made of carbon nanotubes. The density and the bundle structure of the carbon nanotubes can be chosen so that the membrane is transmissive to EUV radiation on the one hand, while, on the other hand, particles are stopped at the membrane and cannot pass through the membrane. The membrane may be provided with a coating in order to provide the membrane with a sufficient resistance to radical ions and molecules. In an alternative embodiment, the pellicle comprises a membrane made of silicon, silicon nitride or any other silicon-containing material. If sufficiently thin, such membranes made of silicon material also provide sufficient transmissivity for EUV radiation.

The pellicle can be arranged such that EUV radiation reflected at the photomask passes through the pellicle prior to entry into the projection lens. The projection lens may comprise a plurality of EUV mirrors, at which the EUV radiation between the photomask and the image sensor is reflected. The optical area of an EUV mirror can be formed by a highly reflective coating. These may be a multilayer coating, especially a multilayer coating having alternating layers of molybdenum and silicon. Using such a coating, it is possible to reflect approximately 70% of the incident EUV radiation. The term EUV radiation is used to refer to electromagnetic radiation in the extreme ultraviolet spectral range with wavelengths of between 5 nm and 100 nm, in particular with wavelengths of between 5 nm and 30 nm.

The projection lens may comprise a first mirror M1, which captures EUV radiation reflected by the photomask. The numerical aperture NA of the projection lens is determined by the dimensions of the first mirror M1. The larger the first mirror M1 in terms of area, the higher the numerical aperture NA of the projection lens. The pellicle may be arranged between the photomask and the first mirror M1 of the projection lens such that EUV radiation reflected at the photomask passes through the pellicle before the EUV radiation is incident on the first mirror M1.

The EUV radiation reflected at the first mirror M1 can be guided to the EUV image sensor via one or more further mirrors of the projection lens. In particular, the EUV radiation can be guided to the image sensor such that an image of the photomask, in particular of an examined partial portion of the photomask, arises on the image sensor.

The projection lens of the measuring device may have a high magnification factor of for example at least 50, preferably at least 100 and more preferably at least 200. An image sensor with a large area in comparison with the imaged partial portion of the photomask is required in order to be able to capture the examined partial portion using an EUV image recording.

For example, the photomask may have an edge length of between 100 mm and 200 mm and/or an area of between 100 cm² and 400 cm². The examined partial portion may have an edge length of between for example 0.1 mm and 5 mm, preferably of between 0.5 mm and 3 mm. If the partial portion is not square, the specification relates to the longer of the edge lengths. If the partial portion is not rectangular either, the specification relates to the largest dimension of the partial portion. The sensor area of the image sensor is preferably larger than the examined partial portion of the photomask, in a manner corresponding to the magnification factor of the projection lens. The dimension of the sensor area of the image sensor, defined like in the case of the examined partial portion, may for example be between 50 mm and 500 mm and preferably be between 100 mm and 200 mm.

The pellicle may additionally be arranged between the illumination system and the photomask such that EUV radiation coming from the illumination system passes through the pellicle before the EUV radiation is incident on the photomask. In other words, the pellicle can be arranged such that the EUV radiation passes through the pellicle twice along the path between the EUV radiation source and the EUV image sensor, specifically once before the reflection at the photomask and once after the reflection at the photomask.

The illumination system may be configured such that a partial portion of the photomask is illuminated. The illumination system may be configured such that the intensity of the EUV radiation is substantially uniform within the illuminated partial portion.

The illumination system may comprise one or more EUV mirrors, at which the EUV radiation on the path between the EUV radiation source and the photomask is reflected. The pellicle may be arranged between the last EUV mirror of the illumination system such that the EUV radiation does not experience another reflection at another EUV mirror of the illumination system before being incident on the photomask.

The measuring device may comprise a vacuum chamber, in which the vacuum is present during the measurement. The projection lens, the illumination system, the EUV radiation source and/or the photomask may be arranged in the vacuum chamber.

It is possible that the measuring device according to the invention comprises further pellicles which are arranged in one or more other sections of the EUV beam path, with the result that the EUV radiation successively passes through a plurality of pellicles. This may comprise further pellicles through which the EUV radiation passes exactly once. In addition or an alternative, this may comprise pellicles which are arranged such that the EUV radiation passes through the relevant pellicle twice.

In an embodiment, the measuring device comprises a first pellicle and a second pellicle, wherein the first pellicle is arranged between the photomask and the projection lens and wherein the second pellicle is arranged between the illumination system and the photomask. With two separate pellicles it is also possible to protect the photomask from particle contaminations, both from the direction of the illumination system and from the direction of the projection lens. The first pellicle and the second pellicle can be arranged such that the EUV radiation passes therethrough exactly once.

The disclosure encompasses further embodiments in which one such pellicle is arranged between the illumination system and the photomask and no pellicle is arranged between the photomask and the projection lens. This may be particularly advantageous if the passage of particles from the projection lens to the photomask is prevented differently.

The pellicle may be fastened to the frame component part in such a way that an opening spanned by the frame is covered by the pellicle. The connection to the measuring device may be established via the frame. The pellicle may be a consumable designed for regular replacement within the scope of servicing measures. The pellicle may need to be replaced if the latter has become contaminated after being used for a certain amount of time.

The frame component part can be attached to a carrying structure of the measuring device when the measuring device is in operation. The carrying structure refers to those parts of the measuring device used to mechanically hold components of the measuring device in position relative to one another. The carrying structure can hold the EUV mirrors of the projection lens in position. In addition or in an alternative, the carrying structure can hold the EUV mirrors of the illumination system in position.

The connection between the frame component part and the carrying structure can be a detachable connection. The detachable connection can be designed such that, should the measuring device be subjected to maintenance, the frame component part can be detached from the carrying structure in order to replace the used pellicle with a new pellicle. The new pellicle can be inserted into the measuring device together with a new frame component part. The maintenance procedure can be performed after a relatively long phase of operation of the measuring device, for example at least a few months, and may comprise maintenance of further components of the measuring device.

The components used to hold the photomask in position during a measurement are also part of the carrying structure of the measuring device. In particular, the measuring device may comprise a carrying component which holds the photomask during a measurement. In an embodiment, the frame component part is attached to the carrying component when the measuring device is in operation.

The carrying component can be a component part of a loading mechanism intended for transportation of the photomask into the measuring device and out of the measuring device. The measuring device may comprise an airlock, within which a pressure adaptation is implemented. The same pressure can be present in both an airlock chamber and the vacuum chamber in a first state of the airlock, with the result that the photomask can be conveyed without pressure difference between the airlock chamber and the vacuum chamber. In a second state of the airlock, a pressure higher than the vacuum pressure and corresponding to the pressure in the surroundings of the airlock may be present in the airlock chamber. The pressure in the second state of the airlock corresponds to atmospheric pressure in an embodiment. In the second state of the airlock, the photomask can be conveyed without pressure difference between the airlock chamber and the surroundings of the airlock.

The loading mechanism can be designed to convey the photomask between a measurement position, which is precisely defined relative to the illumination system and the projection lens, and a position in the airlock chamber. The loading mechanism may comprise actuators suitable to this end. The measuring device may comprise a control unit used to drive the actuators.

The loading mechanism can be designed to convey the carrying component into the airlock chamber together with the photomask. If the pellicle is connected to the carrying component, then said pellicle is also conveyed into the airlock chamber together with the carrying component. The carrying component can be designed such that a photomask unloaded from the measuring device can be taken from the carrying component while the pellicle remains with the carrying component. This can be the norm during the operation of the measuring device, with the result that new photomasks can be repeatedly conveyed into the measuring device while the pellicle remains the same. In this case, the pellicle is only replaced once the pellicle has been used up following the inspection of a plurality of photomasks. It is also possible to replace the pellicle every time a new photomask is introduced into the measuring device. In all cases, the replacement is facilitated if the pellicle is arranged outside of the measuring device together with the carrying component at the time of replacement. For the pellicle replacement, the frame component part can be detached from the carrying component together with the pellicle and can be replaced by a new pellicle with a new frame component part. This exchange of the pellicle can be implemented manually or automatically.

The region of the vacuum chamber in which the photomask is arranged during the measurement can be designed such that, firstly, the same pressure is prevalent there as in the remaining vacuum chamber but that, secondly, an ingress of particles from the remainder of the vacuum chamber into this region of the vacuum chamber is largely avoided. To this end, the photomask can be arranged in a partial chamber which is separated from other regions of the vacuum chamber by a housing wall. The housing wall may be provided with pressure equalization channels, by use of which pressure is equalized between the partial chamber and the remainder of the vacuum chamber. The partial chamber may comprise an opening through which EUV radiation coming from the illumination system enters into the partial chamber and/or through which the EUV radiation reflected to the projection lens exits.

The pellicle may be stretched over the opening such that all EUV radiation entering through the opening into the partial chamber passes through the pellicle, i.e. travels through the pellicle. The pellicle may be sealingly flush with a housing edge surrounding the opening such that a passage of particles between the partial chamber and the remainder of the vacuum chamber at the transition between pellicle and housing is prevented.

In addition or in an alternative to such a pellicle, other measures may be provided in order to prevent particles from being able to be deposited on the photomask. For example, the measuring device may comprise a particle trap in which an electromagnetic beam is created in order to deflect the movement direction of particles. The electromagnetic beam may have a propagation direction which crosses the EUV beam path. The electromagnetic beam can make an angle of at least 30°, preferably an angle of at least 60°, with the EUV beam path.

To prevent the ingress of particles through an area, for example the opening of a partial chamber of the measuring device, it is possible to create a plurality of electromagnetic beams which may be parallel to one another. It is also possible that the propagation direction of a single electromagnetic beam is modified such that the beam covers the area in a scanning procedure. The EUV beam path can intersect the area, especially intersect the latter in a section of the EUV beam path arranged between the illumination system and the photomask and/or between the photomask and the projection lens. The area can make an angle of at least 30°, preferably an angle of at least 60°, with the EUV beam path. For example, the wavelength of the electromagnetic radiation can be between 300 nm and 1200 nm, preferably between 700 nm and 1100 nm. For example, the power of the electromagnetic beam can be between 0.08 W and 1.2 W.

There could also be a particle trap, in which particles are guided along a surface of the measuring device into a region where they are not bothersome. The surface can be a substantially horizontal surface such that particles are deposited on the surface under the influence of gravity. A volume flow setting the particles in motion such that these move over the surface can be created in the vacuum atmosphere. The particles can be collected in a region of the measuring device where they are not bothersome, and/or the particles can be aspirated out of the interior of the measuring device. To this end, use can be made of a vacuum pump which creates a pressure that is lower than the pressure prevalent in the vacuum chamber of the measuring device. The particle trap can be arranged at a radial distance from a section of the EUV beam path such that the particles remain outside of a region in which they can move along the EUV beam path in the direction of the photomask. A volume flow created to move the particles may cross the direction of the EUV beam path and make an angle of at least 30°, preferably an angle of at least 60°, with the section of the EUV beam path.

It is also possible to provide a particle trap in which a volume flow guided through a mesh structure prior to the intersection with the EUV beam path is created in the interior of the measuring device. The volume flow can pass through the mesh structure while particles carried along in the volume flow are deposited on the mesh structure. In this way it is possible to prevent particles from advancing into the region of the EUV beam path.

If such a particle trap is used together with a pellicle according to the invention, then it is possible for a volume flow created for the particle trap and/or an electromagnetic beam created for the particle trap to extend parallel to the pellicle. A volume flow is preferably created such that it does not trigger a pressure difference above the pellicle.

In one embodiment, the device comprises an XY-positioning mechanism, by use of which the position of the photomask within an XY-plane can be modified relative to the incoming EUV beam path. The XY-plane may correspond to the plane of the photomask. The XY-positioning mechanism may be embodied such that the photomask is displaced linearly in the XY-plane. This can be used for a scanning procedure, in which a plurality of EUV image recordings belonging to the same partial portion of the photomask are recorded during a linear movement of the photomask.

In addition or an alternative, the XY-positioning mechanism can also be used to displace the photomask relative to the incident EUV beam path such that it is possible to create aerial images of different partial portions of the photomask. In particular, the XY-positioning mechanism may be designed such that each partial portion of the photomask can be examined.

In addition or an alternative, the XY-positioning mechanism can be used to obtain information about the state of the pellicle. To this end, a reference mask with a known surface structure, for example a uniform surface structure, can be introduced into the measuring device. A statement regarding the state of the pellicle can be made depending on how the image recording changes when the reference mask is displaced in the XY-plane.

The invention also relates to a method for inspecting photomasks, in which EUV radiation emitted by an EUV radiation source is guided via an illumination system to a photomask. EUV radiation reflected at the photomask is guided via a projection lens to an EUV image sensor such that the photomask is imaged on the image sensor. A frame component part of the measuring device carries a pellicle arranged between the photomask and the projection lens (22). The EUV radiation passes through the pellicle.

The disclosure encompasses developments of the method with features which are described in the context of the measuring device according to the invention. The disclosure encompasses developments of the measuring device with features that are described in the context of the method according to the invention.

### BRIEF DESCRIPTION OF DRAWINGS

The invention will be described by way of example below on the basis of advantageous embodiments by reference to the accompanying drawings. In the drawings:

FIG. 1: shows a schematic illustration of a measuring device according to the invention;

FIG. 2: shows a schematic illustration of a photomask;

FIG. 3: shows a detail of the device from FIG. 1 in an enlarged illustration;

FIG. 4: shows the view according to FIG. 3 in an alternative embodiment of the invention;

FIG. 5: shows a schematic illustration of an alternative embodiment of a measuring device according to the invention;

FIGS. 6-8: show the view according to FIG. 3 in alternative embodiments of the invention.

### DETAILED DESCRIPTION

Microlithographic photomasks 17 can be examined using a measuring device according to the invention.

In general, microlithographic photomasks 17 are provided for use in a microlithographic projection exposure apparatus (not depicted here). In the microlithographic projection exposure apparatus, the photomask 17 is illuminated with extreme ultraviolet radiation (EUV radiation) at a wavelength of for example 13.5 nm in order to image a structure formed on the photomask 17 onto the surface of a lithographic object in the form of a wafer. The wafer is coated with a photoresist that reacts to the EUV radiation. The measuring device is used to examine whether the measuring device meets the requirements and is free from contamination.

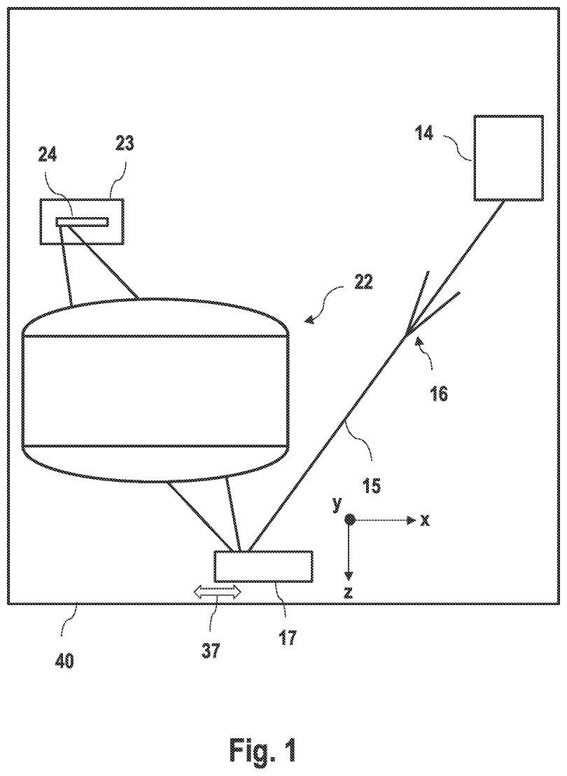

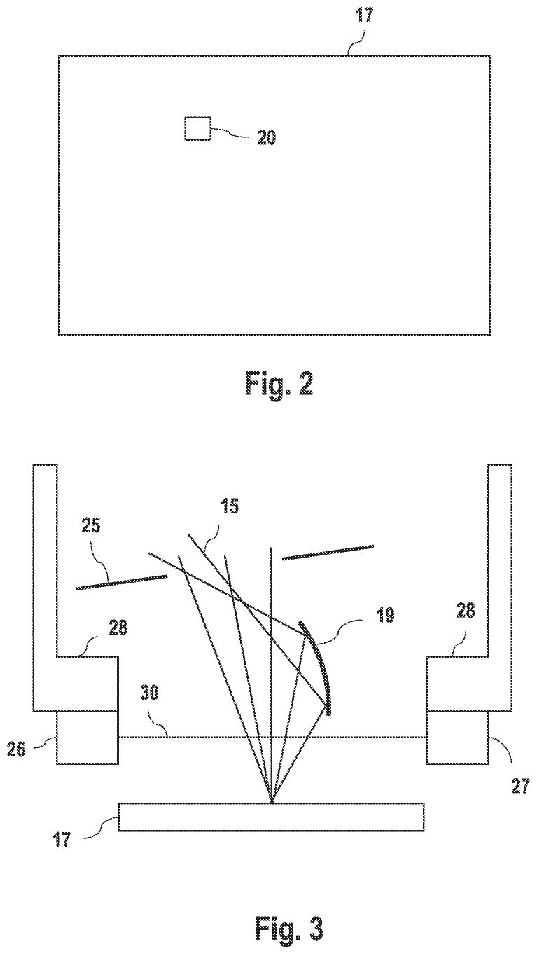

According to FIG. 1, the photomask 17 is arranged in the measuring device such that an EUV beam path 15 emanating from an EUV radiation source 14 is guided via an illumination system 16 to the photomask 17. The illumination system 16 is used to shape the EUV radiation to form a beam used to illuminate, with uniform brightness, an examination field 20 on the surface of the photomask 17. The examination field 20 which is small in comparison with the area of the photomask 17 is depicted in FIG. 2 in an illustration that is not true to scale. For example, the illuminated region 20 may have dimensions of 0.5 mm×0.8 mm. The edge lengths of the photomask 17 can be between 100 mm and 200 mm, for example. A field stop used to delimit the illuminated region to the examination field 20 on the surface of the photomask 17 is arranged in the illumination system 16. Using an XY-positioning mechanism 37, it is possible to move the photomask in the XY-plane in order to bring different examination fields 20 into the region of the EUV beam path.

The EUV beam path 15 reflected at the photomask 17 continues through a projection lens 22 to an EUV camera 23, which is equipped with an image sensor 24, which can be, e.g., a charge coupled device (CCD) sensor, a complementary metal oxide semiconductor (CMOS) sensor, or a time delay and integration (TDI) sensor. The projection lens is used to image the examination field 20 of the photomask 17 on the image sensor 24 of the EUV camera 23. An aperture stop 25 (see FIG. 3) whose aperture corresponds to the first mirror M1 of the projection lens 22 is arranged between the photomask 17 and the first mirror M1. The EUV radiation source 14, the illumination system 15, the photomask 17, the projection lens 22 and the EUV camera 23 are arranged in a vacuum housing 40, in which negative pressure prevails during the operation of the measuring device.

The EUV radiation source 14 is a plasma radiation source, in which the EUV radiation is emitted from a plasma at a wavelength of 13.5 nm. Tin is a medium that can be used to generate a plasma suitable for emitting such EUV radiation. A laser beam can be made to impinge on a droplet of the medium for the purpose of generating the plasma.

The mirrors in the illumination system 16 and the mirrors in the projection lens 22 are designed as EUV mirrors which have a particularly high reflectivity for EUV radiation. The optical area of the EUV mirrors can be formed by a highly reflective coating. These may be a multilayer coating, especially a multilayer coating having alternating layers of molybdenum and silicon. Using such a coating, it is possible to reflect approximately 70% of the incident EUV radiation.

The projection lens 22 has a magnification factor of more than 100. In order to be able to record the entirety of the generated picture of the examination field 20 of the photomask 17, the area of the image sensor 24 is greater than the area of the examination field 20 in accordance with the magnification factor. For example, the image sensor 24 May have dimensions of the order of 100 mm to 200 mm.

A pellicle unit 26 which comprises a frame component part 27 and a pellicle 30 held by the frame component part is arranged above the photomask 17; see FIG. 3. The pellicle unit 26 is arranged both between the photomask 17 and the illumination system 16 and between the photomask 17 and the projection lens 22. The pellicle is positioned between the last mirror 19 in the illumination system 16 and the photomask. This means that the EUV beam path 15 passes through the pellicle 30 twice, specifically once as incoming EUV beam path 15 coming from the illumination system 16 and once as outgoing EUV beam path 15 which was reflected at the photomask 17 and propagates in the direction of the image sensor 24.

The frame component part 27 of the pellicle unit 26 is attached to a carrying structure 28 of the measuring device by way of a screw connection. The carrying structure 28 also keeps the mirrors in the projection lens 22 and the mirrors in the illumination system 16 in position relative to one another.

The pellicle 30 is a very thin membrane made of a carbon nanotube material which allows good passage of the EUV radiation but obstructs the passage of particles. The pellicle 30 is used to protect the photomask 17 from contamination by particles. Particles that arise in the illumination system 16 or in the projection lens 22 and move in the direction of the photomask 17 are incident on the pellicle 30 and deposited there before they can reach the photomask.

The frame component part 27 of the pellicle unit 26 can be detached from the carrying structure 28 of the measuring device within the scope of maintaining the measuring device, in order to replace the used-up pellicle 30 with a new pellicle. The new pellicle 30 can be inserted into the measuring device together with a new frame component part 27 and can be connected to the carrying structure 28.

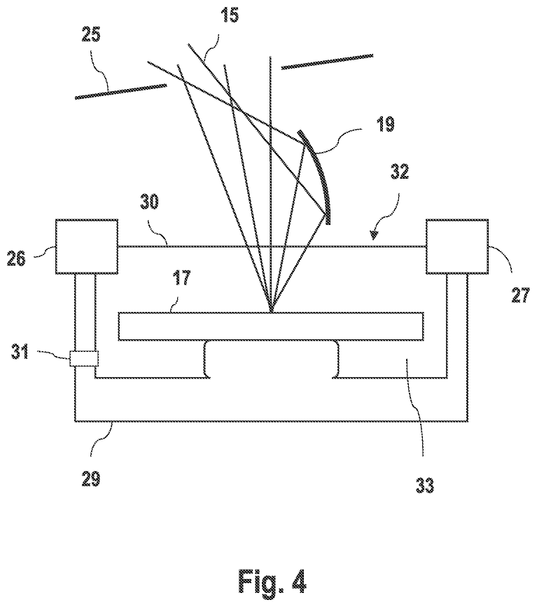

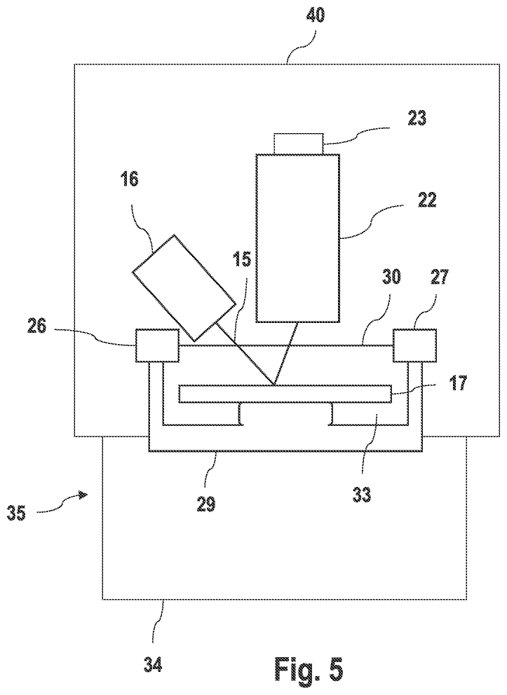

In the exemplary embodiment according to FIG. 4, the pellicle unit 26 is connected to another part of the carrying structure 28, specifically to the carrying component 29 which carries the photomask 17. Together with the pellicle unit 26, the carrying component 29 forms a partial chamber 33 within the vacuum housing 40. The carrying component 29 surrounds an opening 32, through which the EUV beam path 15 enters into the partial chamber 33 and exits from the partial chamber 33. The opening 32 is surrounded by a housing edge of the carrying component 29, to which the frame component part 27 of the pellicle unit 26 is attached. Together with the pellicle unit 26, the carrying component 29 forms a closed-off sleeve for the partial chamber 33, which is only interrupted by a pressure equalization channel 31. Pressure between the partial chamber 33 and the remaining regions of the vacuum housing 40 can be equalized by way of the pressure equalization channel 31.

The carrying component 29 is a constituent part of a loading mechanism 35, by use of which the photomask 17 is introduced into the vacuum housing 40 and removed from the vacuum housing 40. The loading mechanism 35 comprises an airlock chamber 34 which adjoins the vacuum housing 40. The airlock chamber 34 is evacuated to the same pressure that is also prevalent in the vacuum housing 40. Together with the photomask 17 and the pellicle unit 26, the carrying component 29 is displaced into the airlock chamber 34. Subsequently, the connecting opening between the vacuum housing 40 and the airlock chamber 34 is closed and the airlock chamber 34 is brought to ambient pressure. The pressure from the airlock chamber 34 is transferred into the interior of the carrying component 29 via the pressure equalization channel 31. At ambient pressure, the airlock chamber 34 can be opened and the photomask 17 can be taken from the carrying component 29. An opening (not depicted in the figures) in the side wall of the carrying component 29 is opened to this end.

The loading mechanism 35 is actuated multiple times in order to introduce new photomasks 17 into the vacuum chamber 40. In the meantime, the pellicle unit 26 remains unchanged. The pellicle unit 28 is replaced once the pellicle 30 has been used up following the inspection of multiple photomasks 17. This is implemented in an automated process, by virtue of, at ambient pressure, the pellicle unit 26 being released from the carrying component 29 and being replaced by a new pellicle unit. Hence, the carrying component 29 is ready for the inspection of multiple further photomasks 17.

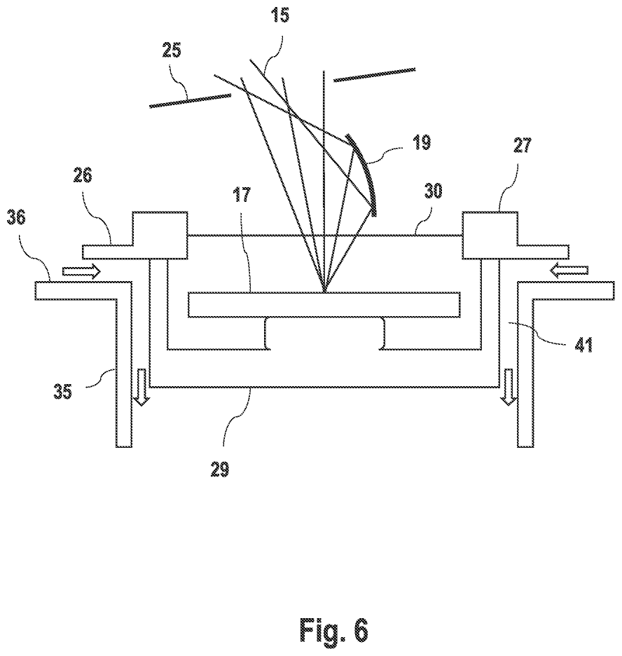

FIG. 6 illustrates an embodiment in which a particle trap is present in addition to the pellicle unit for the purpose of protecting the photomask 17 from contamination. The carrying structure 28 of the measuring device comprises a housing part 35 which extends around the photomask 17. The housing part 35 has a horizontal, upwardly facing surface 36, on which particles can be deposited next to the pellicle unit 26. Particles are aspirated from the surface 36 and removed from the measuring device by way of the application of a negative pressure to a gap 41 existing between the housing part 35 and the carrying component 29. In order to create a volume flow in the desired direction, the negative pressure is lower than the pressure prevalent in the vacuum housing 40.

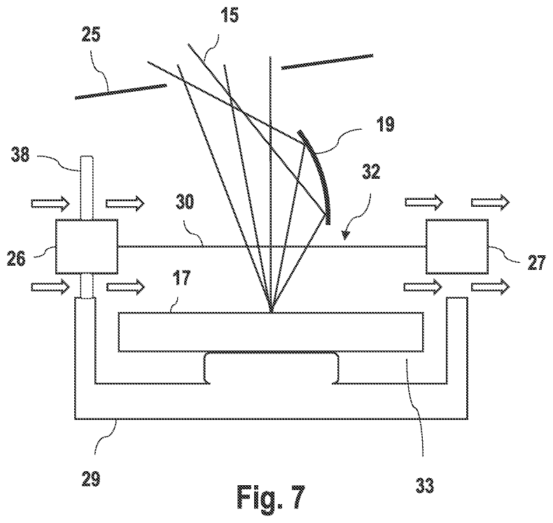

In a further embodiment depicted in FIG. 7, a volume flow, which is oriented parallel to the pellicle 30 and extends above and below the pellicle 30, is created. Prior to entering the region of the pellicle 30, the volume flow is guided through a mesh structure 38 which allows the volume flow to pass but retains particles. This can also make a contribution to protecting the pellicle 30 and the photomask 17 from contamination by particles.

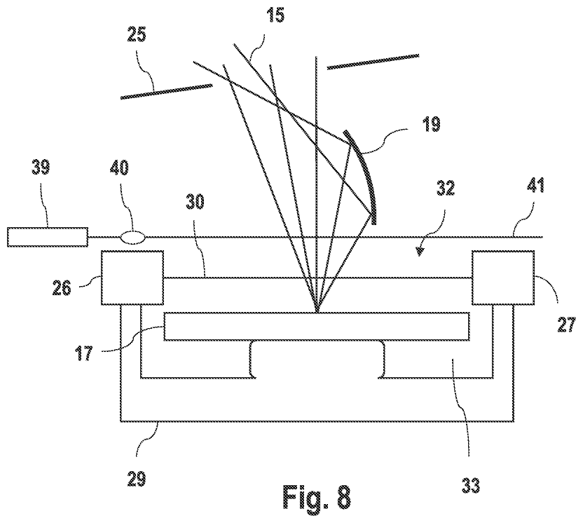

The embodiment according to FIG. 8 comprises a laser 39 which emits a laser beam 41. A scanning device 40 is used to deflect the laser beam within a plane parallel to the pellicle 30 such that the laser beam 41 sweeps over the area spanned by the pellicle 30. As a result of interaction with the laser beam 41, particles are deflected to the side such that they cannot adversely affect the pellicle 30.

Although the present invention has been described with reference to exemplary embodiments, it is modifiable in various ways.

What is claimed is:

1. A measuring device for inspecting photomasks, comprising an illumination system, a projection lens and an EUV image sensor, wherein EUV radiation emitted by an EUV radiation source is guided via the illumination system to a photomask, wherein EUV radiation reflected at the photomask is guided via the projection lens to the EUV image sensor such that the photomask is imaged on the EUV image sensor, and wherein the measuring device comprises a frame component part, wherein the frame component part carries a pellicle and wherein the pellicle is arranged between the photomask and the projection lens such that the EUV radiation reflected at the photomask passes through the pellicle.

2. The measuring device of claim 1, wherein the pellicle is arranged between the illumination system and the photomask such that EUV radiation coming from the illumination system passes through the pellicle.

3. The measuring device of claim 1, comprising a vacuum chamber, in which the projection lens, the illumination system, the EUV radiation source and/or the photomask are arranged.

4. The measuring device of claim 1, wherein the frame component part is detachably connected to a carrying structure of the measuring device.

5. The measuring device of claim 4, wherein the frame component part is detachably connected to a carrying component which is a constituent part of a loading mechanism of the measuring device.

6. The measuring device of claim 5, comprising an airlock chamber, wherein the loading mechanism is designed to convey the pellicle into the airlock chamber.

7. The measuring device of claim 1, wherein the photomask is arranged in a partial chamber of the vacuum chamber and wherein the partial chamber is separated from other regions of the vacuum chamber by a housing wall.

8. The measuring device of claim 7, wherein the partial chamber comprises an opening through which EUV radiation coming from the illumination system enters into the partial chamber and/or through which the EUV radiation reflected to the projection lens exits.

9. The measuring device of claim 8, wherein the pellicle is stretched over the opening.

10. The measuring device of claim 9, wherein the pellicle is sealingly flush with a housing edge surrounding the opening.

11. A measurement system of claim 1, wherein the pellicle consists of a silicon material.

12. A method for inspecting photomasks, wherein EUV radiation emitted by an EUV radiation source is guided via an illumination system to a photomask and wherein EUV radiation reflected at the photomask is guided via a projection lens to an EUV image sensor such that the photomask is imaged on the image sensor, with a frame component part of the measuring device carrying a pellicle arranged between the photomask and the projection lens, and wherein the EUV radiation passes through the pellicle.

13. The method of claim 12, comprising arranging the pellicle between the illumination system and the photomask, and passing EUV radiation coming from the illumination system through the pellicle.

14. The method of claim 12, comprising arranging at least one of the projection lens, the illumination system, the EUV radiation source, or the photomask in a vacuum chamber.

15. The method of claim 1, comprising detachably connecting the frame component part to a carrying structure of the measuring device.

16. The method of claim 15, comprising detachably connecting the frame component part to a carrying component that is a constituent part of a loading mechanism of the measuring device.

17. The method of claim 5, comprising using the loading mechanism to convey the pellicle into an airlock chamber.

18. The method of claim 1, comprising arranging the photomask in a partial chamber of the vacuum chamber, wherein the partial chamber is separated from other regions of the vacuum chamber by a housing wall.

19. The method of claim 18, wherein the partial chamber comprises an opening, and the method comprises at least one of (i) entering EUV radiation coming from the illumination system into the partial chamber through the opening, or (ii) exiting the EUV radiation reflected to the projection lens through the opening.

20. The method of claim 19, comprising stretching the pellicle over the opening.
